(19) United States
(12) Patent Application Publication
(10) Pub. No.: US 2017/0236905 A1
(43) Pub. Date: Aug. 17, 2017

(54) METHOD FOR MANUFACTURING THIN SiC WAFER AND THIN SiC WAFER

(71) Applicant: TOYO TANSO CO., LTD., Osaka (JP)

(72) Inventors: Satoshi Torimi, Kanonji-shi (JP); Masato Shinohara, Kanonji-shi (JP); Youji Teramoto, Kanonji-shi (JP); Norihito Yabuki, Kanonji-shi (JP); Satoru Nogami, Kanonji-shi (JP); Makoto Kitabatake, Kanonji-shi (JP)

(73) Assignee: TOYO TANSO CO., LTD., Osaka (JP)

(21) Appl. No.: 15/360,498

(22) Filed: Nov. 23, 2016

(30) Foreign Application Priority Data
Nov. 26, 2015 (JP) 2015-231063

(51) Int. Cl. H01L 29/16; H01L 21/02; H01L 21/304; H01L 21/306; H01L 21/04; H01L 23/544

(52) U.S. Cl. CPC H01L 29/1608; H01L 21/0475; H01L 23/544; H01L 21/304; H01L 21/30604; H01L 21/02016; H01L 2223/54433

(57) ABSTRACT

Provided is a method for manufacturing a thin SiC wafer by which a SiC wafer is thinned using a method without generating crack or the like, the method in which polishing after adjusting the thickness of the SiC wafer can be omitted. The method for manufacturing the thin SiC wafer 40 includes a thinning step. In the thinning step, the thickness of the SiC wafer 40 can be decreased to 100 μm or less by performing the Si vapor pressure etching in which the surface of the SiC wafer 40 is etched by heating the SiC wafer 40 after cutting out of an ingot 4 under Si vapor pressure.

### BACKGROUND OF THE INVENTION

1. Field of the Invention

The present invention relates mainly to a method for manufacturing a thin SiC wafer and the thin SiC wafer. The method for manufacturing the thin SiC wafer is to perform a thinning step to a SiC wafer.

2. Description of the Related Art

Recently, a thin SiC wafer is demanded for downsizing of a semiconductor device, reduction of on□resistance and the like. Patent Document 1 (Japanese Patent Application Laid-Open No.2014-229843), Patent Document 2 (Japanese Patent No.5550738), and Non-Patent Document 1 (“Performance of a 650V SiC diode with reduced chip thickness”, Material Science Forum) disclose a treatment for thinning a SiC wafer. For example, Non-Patent Document 1 discloses that a SiC wafer is made thin by mechanically grinding the SiC wafer using a diamond wheel or the like.

Patent Document 3 (Japanese Patent Application Laid-Open No. 2011-247807) discloses a Si vapor pressure etching in which etching is performed by heating a SiC wafer under Si vapor pressure. Patent Document 3 discloses a treatment in which a surface roughness caused by mechanical polishing and the like is planarized by performing the Si vapor pressure etching to the SiC wafer that is mechanically ground and polished.

Non-Patent Document 2 (“Thinning of a two-inch silicon carbide wafer by plasma chemical vaporization machining using a slit electrode”, Material Science Forum) and Non-Patent Document 3 (“Polishing Characteristics of 4H—SiC Si-face and C-face by Plasma Chemical Vaporization Machining”, Material Science Forum) disclose a treatment in which a surface of a SiC wafer is removed by performing plasma CVM (Chemical Vaporization Machining). Non-Patent Document 2 discloses a treatment in which the SiC wafer that is mechanically ground and polished is thinned to about 60 μm by performing plasma CVM.

Patent Document 4 (Japanese Patent Application Laid-Open No. 2014-75380) discloses a configuration in which a mark is preformed on a seed crystal by laser machining, cutting using a diamond cutting tool, dry etching, ion implantation or the like, and the mark is kept at a time of forming the SiC wafer.

### SUMMARY OF THE INVENTION

However, when mechanical grinding is performed as described in Patent Document 1, 2 and Non-Patent Document 1, the rate of grinding is increased by applying the pressure to the SiC wafer at a time of grinding. This causes the SiC wafer to be applied the processing damage and the stress, which leads to distortion or the like in a crystal. As a result, a modified layer may be formed on the SiC wafer, or the SiC wafer may be cracked. Non-Patent Document 1 discloses that the thickness of a limit of processing is 110 μm when mechanically grinding since hairline crack is formed if the thickness is 110 μm or less after mechanically grinding. Additionally, since the surface roughness is large when mechanically grinding steps such as mechanical polishing and chemical mechanical polishing are then needed.

Patent Document 3 does not disclose the thickness of the SiC wafer at all. In Patent Document 3, the Si vapor pressure etching is performed not for thinning the SiC wafer but for removing the surface roughness of the SiC wafer. In other words, the Si vapor pressure etching is performed to the SiC wafer in which the thickness has been already adjusted by mechanical grinding.

Non-Patent Document 2 discloses a method for performing plasma CVM to the SiC wafer after mechanically grinding, similarly to Patent Document 3. In general, in plasma CVM, it takes more time for the SiC wafer to be thinned because of low etching rate, as compared with the Si vapor pressure etching.

The present invention has been made in view of the circumstances described above, and a primary object of the present invention is to provide a method for manufacturing a thin SiC wafer, the method which can omit a polishing step after adjusting the thickness of a SiC wafer while thinning the SiC wafer using a method which does not cause crack or the like.

Problems to be solved by the present invention are as described above, and next, means for solving the problems and effects thereof will be described.

In a first aspect of the present invention, in a method for manufacturing a thin SiC wafer by processing a SiC wafer after cutting out of an ingot, a method including a thinning step of thinning the thickness of the SiC wafer after cutting out of the ingot is provided. In the thinning step, a Si vapor pressure etching for etching the surface of the SiC wafer is performed by heating the SiC wafer under Si vapor pressure, which can decrease the thickness to 100 μm or less.

Accordingly, in the Si vapor pressure etching, since the processing damage and the stress are not applied to the SiC wafer during the etching, hairline crack or the like is not occurred even if the SiC wafer is thinned to 100 μm or less. Since the Si vapor pressure etching enables the surface to be planarized at a molecular level, a polishing step is unnecessary. Furthermore, since the Si vapor pressure etching can be performed at a high speed, the thinning step can be performed in a short time even in a case of considerably thinning the SiC wafer.

The SiC wafer having the thickness decreased by using the Si vapor pressure etching has a higher strength than that of the SiC wafer having the thickness decreased by using a mechanical polishing. This can compensate for the decrease in the strength that is caused by thinning the SiC wafer.

In the method for manufacturing the thin SiC wafer, in the thinning step, it is preferable that the Si vapor pressure etching is performed to the SiC wafer after cutting out of the ingot while the SiC wafer is not subjected to a mechanical grinding for adjusting the thickness of the SiC wafer.

Accordingly, instead of the mechanical grinding for adjusting the thickness, the Si vapor pressure etching can be performed, which can reduce the number of steps.

For the method for manufacturing the thin SiC wafer, in the thinning step, it is preferable that the thickness of the SiC wafer is decreased while removing the surface roughness of the SiC wafer which is formed at a time of cutting out of the ingot.

Accordingly, after the cutting out of the ingot, the Si vapor pressure etching is performed to the SiC wafer on which the processing such as grinding and polishing are not performed much, which allows the SiC wafer to be thinned and its surface to be planarized.

For the method for manufacturing the thin SiC wafer, in the thinning step, it is preferable that the thickness of the SiC wafer is removed by 100 μm or more.

Accordingly, since the Si vapor pressure etching can be performed at a high speed, even if the SiC wafer is removed to 100 μm or more, the thinning step can be performed in a short time while completely removing the processing damage which occurs until the above-described step.

For a method for manufacturing the thin SiC wafer, in the Si vapor pressure etching performed in the thinning step, it is preferable that the etching rate of the surface to be treated is 500 nm/min or more.

Accordingly, since the etching rate of 500 nm/min or more can be achieved if the Si vapor pressure etching is performed under an appropriate condition, the thinning step can be performed in a short time even in a case of considerably thinning the SiC wafer.

Preferably, the method for manufacturing the thin SiC wafer is as follows. That is, in the surface of the SiC wafer, if the surface for forming an epitaxial layer is regarded as a main surface, in the thinning step, both of the main surface of the SiC wafer and a back surface of the main surface are etched.

This can remove the surface roughness of the main surface and the back surface concurrently. The concurrent etching of both of surfaces makes it possible to etch at a high rate.

For the method for manufacturing the thin SiC wafer, in the thinning step, it is preferable that the Si vapor pressure etching is performed to the SiC wafer having a mark that shows information by removing the surface to be formed into a predetermined shape.

Accordingly, in the Si vapor pressure etching, unlike a mechanical polishing and grinding, since a region recessed from the surface of the SiC wafer can also be etched, the mark can be remained even if the thinning step is performed. Therefore, since it is unnecessary to form the mark on the thin SiC wafer, cracking in the thin SiC wafer can be prevented.

In the method for manufacturing the thin SiC wafer, it is preferable to perform, prior to the thinning step, a mark forming step of forming the mark on the SiC wafer.

Accordingly, as described above, in the Si vapor pressure etching, since the mark is remained after the thinning step, the mark forming step can be performed before the thinning step.

For the method for manufacturing the thin SiC wafer, in the thinning step, the Si vapor pressure etching is preferably performed such that the amount of etching is varied depending on a position of the SiC wafer.

Accordingly, in the Si vapor pressure etching, since the amount of etching in each region of the SiC wafer can be controlled depending on a condition, a SiC wafer having a desired shape can be manufactured.

For the method for manufacturing the thin SiC wafer, in the thinning step, it is preferable to perform the Si vapor pressure etching such that the thickness in an outer edge region of the SiC wafer is larger than the thickness in the central region.

This can improve a mechanical strength of the SiC wafer.

For the method for manufacturing the thin SiC wafer, in the thinning step, it is preferable that the SiC wafer is chamfered while decreasing the thickness of the SiC wafer.

Accordingly, the Si vapor pressure etching can be performed not only in the thinning step but also in the processing of an outer circumferential surface.

In a second aspect of the present invention, in a method for manufacturing a thin SiC wafer by processing a SiC wafer after cutting out of the ingot, a method including a thinning step for thinning the thickness of the SiC wafer after cutting out of the ingot is provided. In the thinning step, after the thickness of the SiC wafer is thinned by mechanically grinding, the thickness is further thinned by performing a Si vapor pressure etching in which the surface of the SiC wafer is etched by heating the SiC wafer, so that the thickness is decreased to 100 μm or less.

Accordingly, even if the Si vapor pressure etching is performed after cutting and mechanically grinding, the surface is planarized at a molecular level. This can manufacture the SiC wafer having a high strength without a polishing step.

In a third aspect of the present invention, the surface of the SiC wafer has a mark that shows information depending on a shape that is formed into a predetermined shape by removing. Accordingly, a thin SiC wafer having the thickness of 100 μm or less is provided.

Conventionally, since the thinning step is performed by mechanically grinding, the mark is removed during the thinning step if the mark is formed before the thinning step. On the other hand, when the mark is formed on the thin SiC wafer after the thinning step, the SiC wafer is cracked. In this regard, the thin SiC wafer having the mark can be achieved by performing the Si vapor pressure etching.

Preferably, the SiC wafer is configured as follows. That is, it means a wafer before forming an epitaxial layer. The SiC wafer includes a region having the hardness of 27 GPa or more on the surface measured under the condition having the load of 500 mN or the indentation of 1 μm using nano indentation method.

Preferably, the SiC wafer is configured as follows. That is, the epitaxial layer is formed on the surface. The SiC wafer includes a region having the hardness of 29.5 GPa or more on the surface of the epitaxial layer measured under the condition having the load of 500 mN or the indentation of 1 μm using nano indentation method.

Preferably, the SiC wafer is configured as follows. That is, it means a wafer before forming the epitaxial layer. The SiC wafer has a higher hardness, compered to the SiC wafer in which the chemical mechanical polishing is performed on the surface measured under the condition having the load of 500 mN or the indentation of fpm using nano indentation method.

The SiC wafer using the above-described Si vapor pressure etching has the high strength as compared with the SiC wafer using the conventional chemical mechanical polishing, which can compensate for decrease in the strength due to thinning of the SiC wafer.

### BRIEF DESCRIPTION OF THE DRAWINGS

FIG. 1 is a diagram illustrating outline of a high temperature vacuum furnace for using in a Si vapor pressure etching of the present invention;

FIG. 2 is a diagram schematically showing a step for manufacturing a SiC wafer for a conventional epitaxial forming;

FIG. 3 is a diagram schematically showing a step for manufacturing a SiC wafer for an epitaxial forming of this embodiment;

FIG. 4 is photomicrographs showing situation before and after the Si vapor pressure etching on Si-face and C-face;

FIG. 5 is a graph showing a relationship between the rate of etching and the temperature on Si-face and C-face;

FIG. 6 is a graph showing a relationship between the rate of etching and the pressure of inert gas;

FIG. 7A is a photomicrograph of a mark before the Si vapor pressure etching, FIG. 7B is a graph showing a measurement result of the width and the depth of the mark;

FIG. 8A is a photomicrograph of the mark after the Si vapor pressure etching, and FIG. 8B is a graph showing a measurement result of the width and depth of the mark;

FIG. 9 is a diagram schematically showing a step for manufacturing a SiC wafer for an epitaxial forming of a first modification;

FIG. 10A and FIG. 10B include a graph showing a distribution of the thickness of a SiC wafer before the Si vapor pressure etching;

FIG. 11 is a graph showing a distribution of the thickness of a SiC wafer after the Si vapor pressure etching;

FIG. 12 is a diagram schematically showing a step for manufacturing a SiC wafer for an epitaxial forming of a second modification;

FIG. 13 is a graph showing a distribution of the amount of etching after the Si vapor pressure etching;

FIG. 14 is a diagram showing Weibull distribution as a result of measuring the hardness of a SiC wafer after chemical mechanical polishing and the hardness of a SiC wafer after the Si vapor pressure etching using nano indentation method; and

FIG. 15 is a diagram showing Weibull distribution as a result of measuring the hardness of a SiC wafer formed an epitaxial layer after chemical mechanical polishing and the hardness of a SiC wafer in which an epitaxial layer is formed after the Si vapor pressure etching using nano indentation method.

### DETAILED DESCRIPTION OF THE PREFERRED EMBODIMENTS

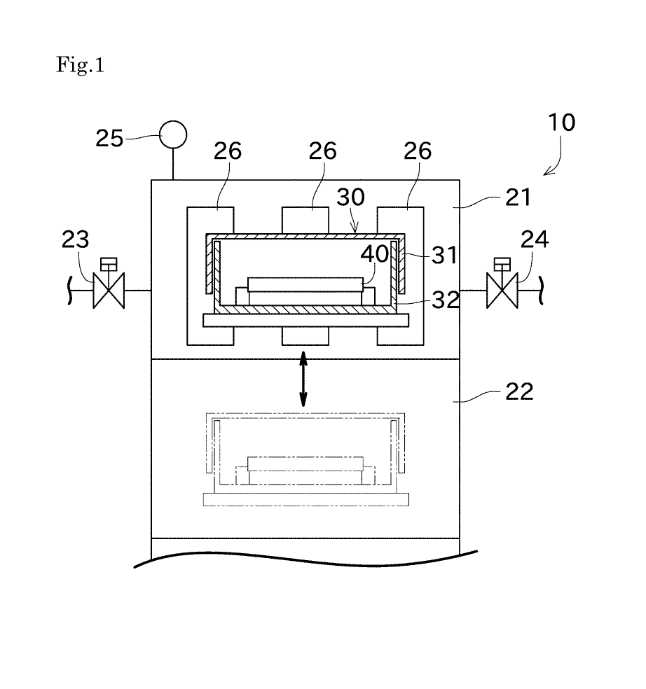

Next, an embodiment of the present invention will be described with reference to the drawings. Firstly, referring to FIG. 1, a high temperature vacuum furnace 10 used for a heat treatment of this embodiment will be described.

As shown in FIG. 1, the high temperature vacuum furnace 10 includes a main heating chamber 21 and a preheating chamber 22. The main heating chamber 21 is configured to heat a SiC wafer 40 made of, at least in its surface, single crystal 4H—SiC or the like, up to a temperature of 1000° C. or more and 2300° C. or less. The preheating chamber 22 is a space for preheating the SiC wafer 40 prior to heating in the main heating chamber 21.

A vacuum-forming valve 23, an inert gas injection valve 24, and a vacuum gauge 25 are connected to the main heating chamber 21. The vacuum-forming valve 23 is configured to adjust the degree of vacuum of the main heating chamber 21. The inert gas injection valve 24 is configured to adjust pressure of an inert gas (for example, Ar gas) within the main heating chamber 21. The vacuum gauge 25 is configured to measure the degree of vacuum within the main heating chamber 21.

Heaters 26 are provided in the main heating chamber 21. Heat reflection metal plates (not shown) is secured to a side wall and a ceiling of the main heating chamber 21. The heat reflection metal plates are configured to reflect heat of the heaters 26 toward a central region of the main heating chamber 21. This provides strong and uniform heating of a SiC substrate 40, to cause a temperature rise up to 1000° C. or more and 2300° C. or less. Examples of the heaters 26 include resistive heaters and high-frequency induction heaters.

The SiC wafer 40 stored in a crucible (storing container) 30 is heated by the high temperature vacuum furnace 10. The crucible 30 is placed on an appropriate support or the like, and the support is movable at least in a range from the preheating chamber to the main heating chamber. The crucible 30 includes an upper container 31 and a lower container 32 that are fittable with each other. The lower container 32 of the crucible 30 can support the SiC wafer 40 so as to expose both a main surface and a back surface ((0001) plane and (000-1) plane (Si-face and C-face) when expressed by the crystal plane) of the SiC wafer 40. Here, the main surface means one of two largest regions on the plane of the SiC wafer 40, that is the surface where an epitaxial layer is formed in the following step. The back surface means a back side surface of the main surface.

For the crucible 30, in its portion constituting wall surfaces (an upper surface, side surfaces, and a bottom surface) of the internal space in which the SiC wafer 40 is stored, a tantalum layer (Ta), tantalum carbide layers (TaC and Ta₂C), and a tantalum silicide layer (TaSi₂ or TacSi₃, etc.) are provided in this order from the outside toward the internal space side.

The tantalum silicide layer supplies Si to the internal space by heating. Since the crucible 30 includes the tantalum layer and the tantalum carbide layer, the surrounding C vapor can be taken in. Accordingly, a high-purity Si atmosphere can be kept in the internal space at a time of heating. Instead of the tantalum silicide layer, solid Si or the like may be arranged. In this case, the solid Si sublimes at a time of heating, so that a high-purity Si atmosphere can be kept in the internal space.

In heating the SiC wafer 40, the crucible 30 is firstly placed in the preheating chamber 22 of the high temperature vacuum furnace 10 as indicated by the dot-dash lines in FIG. 1, and preheated at an appropriate temperature (for example, about 800° C.). Then, the crucible 30 is moved to the main heating chamber 21 whose temperature has been elevated to a set temperature (for example, about 1800° C.) in advance. Then, the SiC wafer 40 is heated while adjusting the pressure or the like. The preheating may be omitted.

Next, a Si vapor pressure etching performed in this embodiment will be described. In this embodiment, the SiC wafer 40 having an off angle is stored in the crucible 30, and heated using the high temperature vacuum furnace 10 under high-purity Si vapor pressure in a range of 1500 □ or more and 2200 □ or less, desirably 1600 □ and 2000 □ or less. The SiC wafer 40 is heated under this condition, and thereby the surface is etched and planarized. In this Si vapor pressure etching, the following reactions are performed. To explain it briefly, the SiC wafer 40 is heated under Si vapor pressure, and thereby the pyrolysis and the chemical reaction with Si cause SiC in the SiC wafer 40 to change into Si₂C or SiC₂, etc. and sublime. In addition, the Si under Si atmosphere is bonded with C on the surface of the SiC wafer 40 and the self-organization is caused, which can planarize the surface.

SiC(s)→Si(v)I+C(s)I (1)

2SiC(s)→Si(v)II+SiC₂(v) (2)

SiC(s)+Si(v)I+II→Si₂C(v) (3)

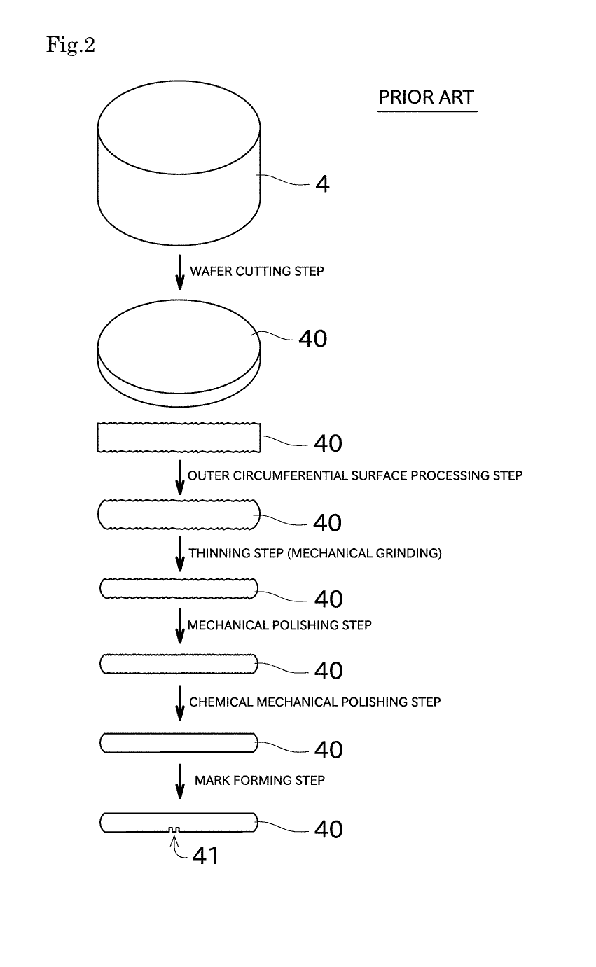

Next, a step for manufacturing the SiC wafer 40 for an epitaxial forming using an ingot 4 will be described. Firstly, the conventional manufacturing step will be described with reference to FIG. 2.

As shown in FIG. 2, the ingot 4 is firstly cut at a predetermined interval using cutting means such as a diamond wire, and thereby the plurality of SiC wafers 40 is cut out of the ingot 4 (a wafer cutting step). The SiC wafer 40 (as-sliced wafer) cut out as above has, in its main surface and back surface, a large surface roughness formed at a time of cutting. FIG. 2 schematically shows a perspective view and a sectional view of the SiC wafer 40.

Next, chamfering by mechanical treatment is performed on an outer circumferential surface of the SiC wafer 40 (a surface parallel to the thickness direction, surfaces vertical to or substantially vertical to the main surface) (an outer circumferential surface processing step). Such chamfering may include, as shown in FIG. 2, round chamfering that forms a predetermined arc on the outer circumferential surface or chamfering that cut out diagonally at a predetermined angle.

Next, mechanical grinding by a diamond wheel or the like is performed on the main surface or the back surface of the SiC wafer 40 (a thinning step). The thinning step is a step for obtaining the desired thickness of the SiC wafer 40. When the thinning step is performed by mechanical grinding, the surface of the SiC wafer 40 has been still roughed. Therefore, a mechanical polishing step and a chemical mechanical polishing step are performed, so that the surface of the SiC wafer 40 is planarized.

After that, for example, the laser is irradiated on the surface (the main surface or the back surface) of the SiC wafer 40 and the surface is selectively removed (grooves are selectively formed), and thereby a mark 41 is formed. The mark 41 shows the information (characters, symbols, bar codes, etc.) for identifying the SiC wafer 40 depending on the removed shapes. As above, the SiC wafer before forming the epitaxial layer (that is, the SiC wafer for forming the epitaxial layer or an epi ready wafer) is manufactured. The method for manufacturing the SiC wafer 40 for the epitaxial forming includes the various methods, and the above-described method is merely an example.

Here, recently, the thin SiC wafer 40 (for example, its thickness of 100 μm or less) is demanded for the purpose of downsizing of a semiconductor device and on□resistance reduction. However, when the SiC wafer 40 is manufactured using the conventional method, the following problems are present. That is, when manufacturing the thin SiC wafer 40, the SiC wafer 40 needs to be ground until the SiC wafer 40 is thinned in the thinning step. However, as described in Non-Patent Document 1, in the mechanical grinding, since cracks are generated when the thickness is 110 μm or less, the thin SiC wafer 40 cannot be manufactured. If the thin SiC wafer 40 is manufactured, the pressure is applied to the SiC wafer 40 in the mechanical polishing step, which may form the modified layer on the SiC wafer 40 or may cause cracking of the SiC wafer 40. Furthermore, when the mark 41 is formed on the thin SiC wafer 40, the SiC wafer 40 may be cracked. However, when the mark 41 is formed prior to the thinning step, the mark 41 is disappeared since the regions other than grooves in the mark 41 is ground in the thinning step. As such, in the conventional method, it was difficult to manufacture the thin SiC wafer 40 (particularly the SiC wafer 40 having the mark 41).

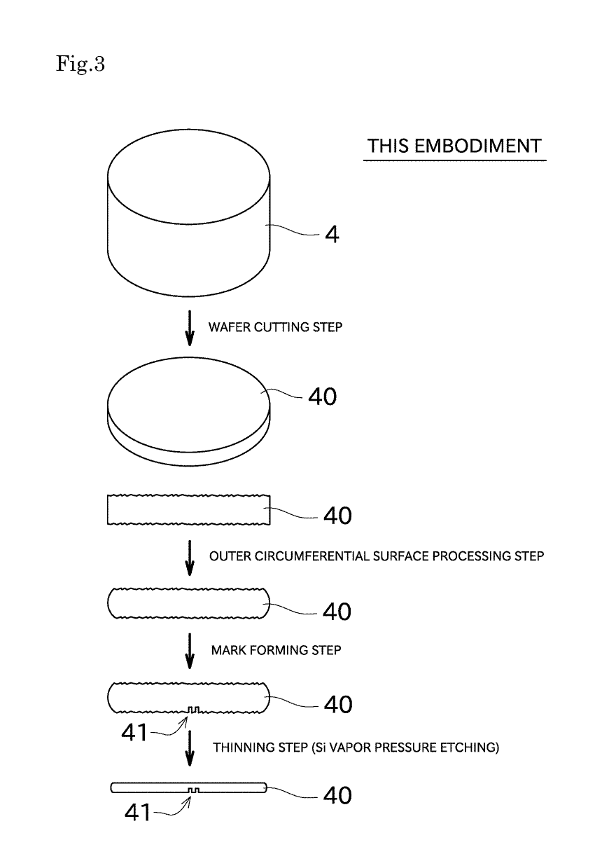

On the other hand, in this embodiment, the thin SiC wafer 40 for the epitaxial forming can be easily and surely manufactured. In the following, a method for manufacturing the thin SiC wafer 40 of this embodiment will be described with reference to FIG. 3.

The method for manufacturing of this embodiment firstly performs, similarly to the conventional method, a wafer cutting step and an outer circumferential surface processing step. Then, a mark forming step is performed. In the conventional method, the mark forming step is performed at last, however, in this embodiment, the mark forming step is performed prior to the thinning step. The wafer cutting step, the outer circumferential surface processing step, and the mark forming step in this embodiment are as described in the conventional invention.

After that, the SiC wafer 40 having the mark 41 is stored in the crucible 30, and then the Si vapor pressure etching is performed to the SiC wafer 40 using the high temperature vacuum furnace 10 (the thinning step). In the thinning step, the Si vapor pressure etching is performed until the thickness of the SiC wafer 40 is 100 μm or less (desirably, 70 μm or less). The thinning step by mechanically grinding is not performed (that is, the Si vapor pressure etching is performed to the SiC wafer 40 without the mechanical grinding for adjusting the thickness). For the detailed description regarding the thickness, it means that the average thickness is 100 μm or less, etc. although variations of the thickness of the SiC wafer 40 are existing. When keeping the thickness only in a part of the SiC wafer 40, it means that the thickness in the central region of the SiC wafer 40 (that is, a region where the epitaxial layer is formed or the semiconductor device is formed) is 100 μm or less, etc. For the SiC wafer 40 which is divided into a chip size or the like of the semiconductor device by forming grooves on the surface, it means the thickness in the region (the region where the epitaxial layer is formed or the semiconductor device is formed) other than that having the grooves.

In the following, main three advantages for performing the thinning step by the Si vapor pressure etching will be briefly described. (1) In the Si vapor pressure etching, since the surface is planarized at a molecular level while etching, the subsequent polishing step is unnecessary. (2) In the Si vapor pressure etching, although the details will be described later, the etching rate can be controlled by changing the conditions or the like. Therefore, the SiC wafer 40 can be etched at a high rate (for example, 500 nm/min). Particularly in this embodiment, since the main surface and the back surface of the SiC wafer 40 are etched simultaneously, the thickness of the SiC wafer 40 may reach 100 μm or less very quickly. The main surface and the back surface are etched simultaneously, which leads to the advantage in which both of the surfaces can be planarized simultaneously (in the plasma CVM, since both of the surfaces of the SiC wafer cannot be processed simultaneously, the disadvantage in which one side of the SiC wafer cannot be sufficiently planarized is present. Non-Patent Document 3 discloses such situation.). (3) Since the Si vapor pressure etching is vapor phase etching, the bottom of the groove formed as the mark 41 is etched.

Therefore, in this embodiment, the mark 41 can be left even after performing the thinning step. In Patent Document 3, the Si vapor pressure etching is performed after the thickness of the SiC wafer 40 is adjusted by the mechanical grinding step and after the mechanical polishing is further performed. Therefore, intended use in Patent Document 3 is different from this embodiment. It is considered that the etching rate and the etching amount are considerably varied as well.

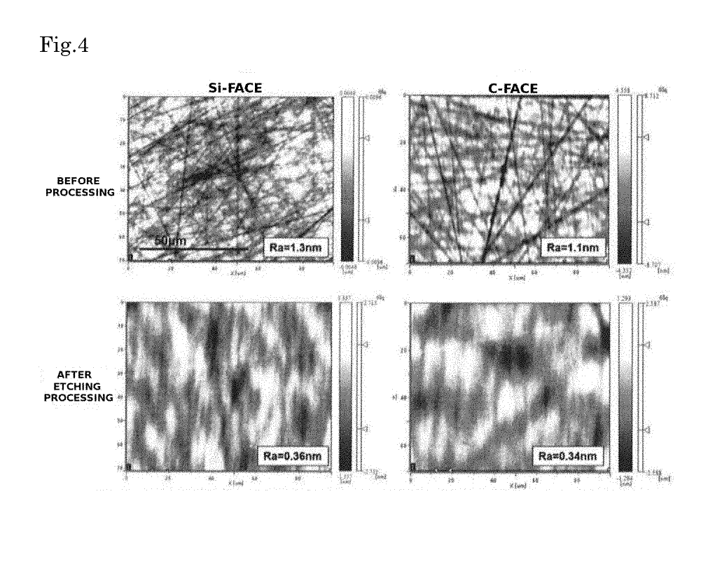

Next, the details of the above-described effects will be described based on the experiment data or the like. Firstly, the planarization by the Si vapor pressure etching will be described with reference to FIG. 4.

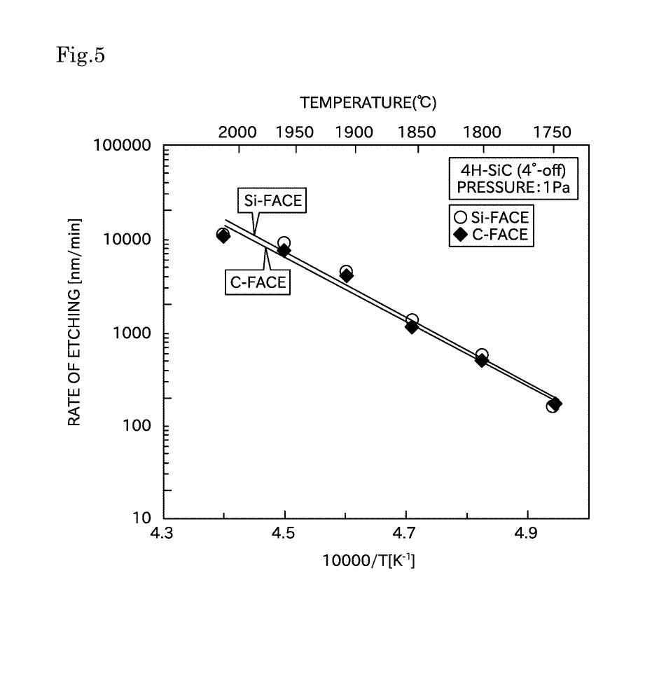

FIG. 4 illustrates photomicrographs showing situation before and after the Si vapor pressure etching on Si-face and C-face. These photomicrographs show that, on both Si-face and C-face, the Si vapor pressure etching enables to remove the surface roughness or the like caused by cutting out and to planarize the surface. Therefore, in this embodiment, a process for decreasing the thickness of the SiC wafer, and a process for removing the surface roughness can be performed simultaneously. In this embodiment, since the etching is performed on both Si-face and C-face, each of Si-face and C-face corresponds to the surface to be treated. The change of the surface roughness described in FIG. 5 shows that the surface is planarized. The Si vapor pressure etching enables the surface to be planarized more than that when performing the chemical mechanical polishing.

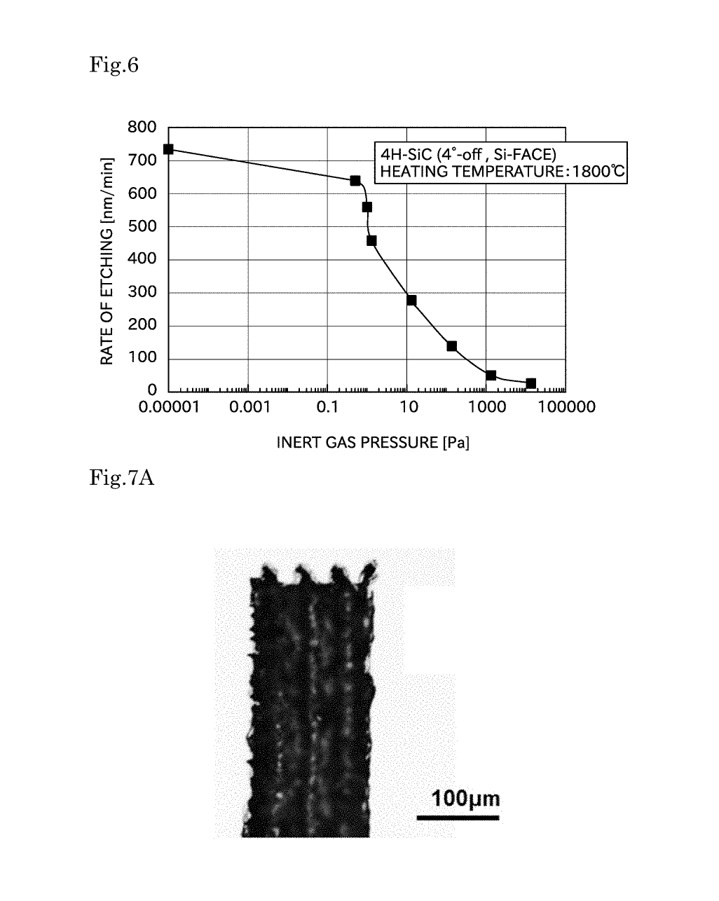

Next, controlling of the etching rate of the Si vapor pressure etching will be described with reference to FIG. 5 and FIG. 6.

One of the parameters that controls the etching rate of the SiC wafer 40 is a heating temperature. FIG. 5 is the Arrhenius plot graph showing the change of the etching rate when the heating temperature is changed from 1750 □ to near 2000 □. The change of the etching rate is plotted with respect to Si-face and C-face individually. The graph shows that the etching rate is increased as the heating temperature is increased. The horizontal axis of the graph represents the reciprocal of the temperature, and the vertical axis of the graph logarithmically represents the rate of etching. As shown in FIG. 5, the graph is linear. This makes it possible to, for example, estimate the rate of etching that will be obtained if the temperature is changed.

The other parameter that controls the etching rate of the SiC wafer 40 is the pressure of the inert gas. FIG. 6 is a graph showing a relationship between the inert gas pressure and the rate of etching. The graph shows that the etching rate is decreased as the pressure of the inert gas is increased. For example, in a case of the heating temperature of 1800 □, the pressure of 1 Pa or less enables the etching rate on one surface (Si-face in FIG. 6) to be about 500 nm/min or less. The pressure of 10 Pa or more enables the etching rate to be about 300 mn/min or less. In a case of the small etching amount, the etching rate may be set lower, which can accurately estimate the etching amount. It is also possible that the etching is firstly performed under the condition of high etching rate. Then, necessary etching amount is calculated by measuring the thickness of the SiC wafer 40. Then, the etching may be performed while accurately controlling the etching amount under the condition of low etching rate.

The etching rate of the SiC wafer 40 is also varied depending on Si supply source, for example. When solid Si (Si pellets) are arranged within the crucible 30, the suppliability of Si is varied depending on the number of arrangement and its position. The high suppliability of Si can increase the etching rate of the SiC wafer 40.

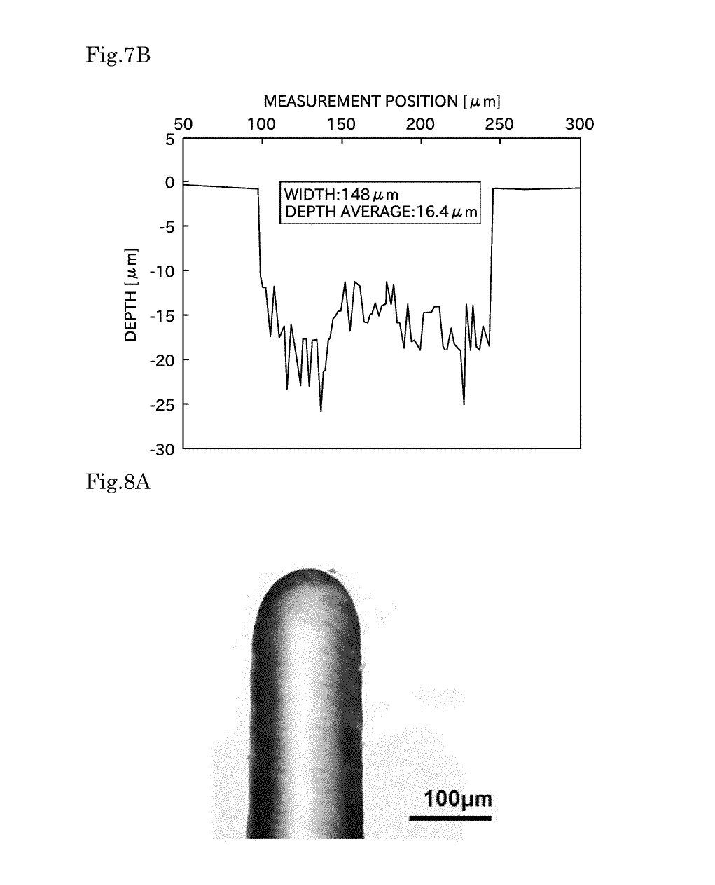

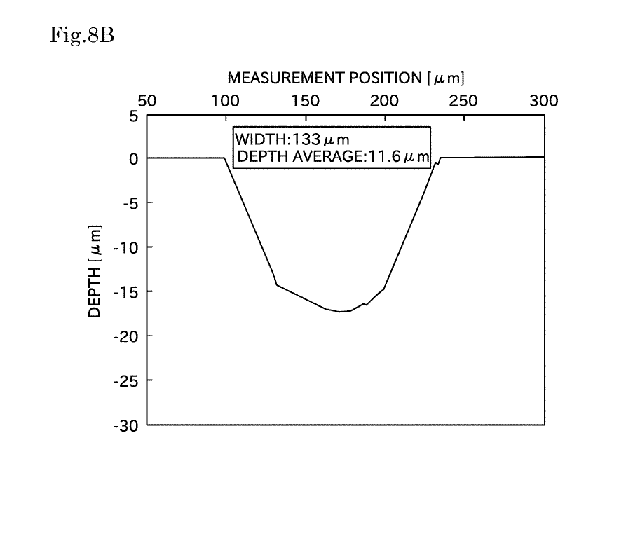

Next, the fact that the mark 41 remains even if the Si vapor pressure etching is performed will be described with reference to FIG. 7A, FIG. 7B, FIG. 8A and FIG. 8B.

FIG. 7A is a photomicrograph of the mark 41 before the Si vapor pressure etching. FIG. 7B is a graph showing a measurement result of the width and the depth of the mark 41. In this experiment, the thickness of the SiC wafer 40 prior to the Si vapor pressure etching (prior to the thinning step) was 350 μm. As shown in FIG. 7A and FIG. 7B, the mark 41 prior to the Si vapor pressure etching had the large variation in the depth direction. Although it cannot be read from FIG. 7A and FIG. 7B, the modified layer occurred by laser processing is existing.

FIG. 8A is a photomicrograph of the mark 41 after the Si vapor pressure etching. FIG. 8B is a graph showing the measurement result of the width and depth of the mark 41. In this experiment, the thickness of the SiC wafer 40 after the Si vapor pressure etching (after the thinning step) was 6.5 μm. As shown in FIG. 8A and FIG. 8B, the mark 31 remained regardless of the etching of about 300 μm. Before and after the Si vapor pressure etching, the width of the mark 41 had little change. Although the average depth of the mark 41 was slightly decreased by being planarized, the sufficient depth as the mark 41 remained. Additionally, although it cannot be read from FIG. 8A and FIG. 8B, the modified layer occurred by laser processing is removed by the Si vapor pressure etching.

As such, in this embodiment, the mark 41 can remain even if the thinning step is performed. This can prevent the SiC wafer 40 from cracking in forming the mark 41 after the thinning step.

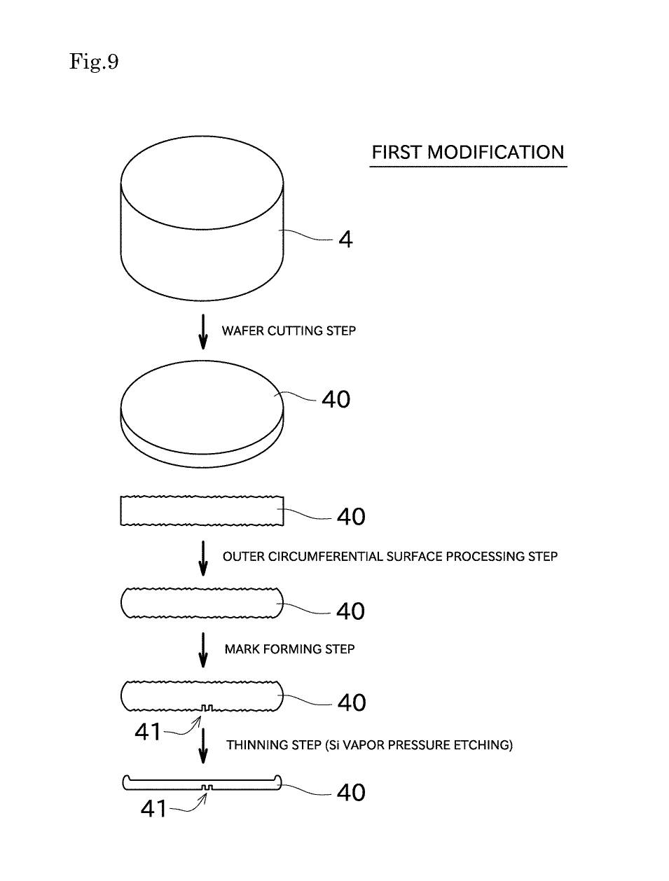

Next, a first modification of the above-described embodiment will be described with reference to FIG. 9 to FIG. 11. In a description of this modification, configuration parts identical or similar to those of the above-described embodiment will be denoted by the same reference numerals as those of the above-described embodiment, and descriptions thereof may be omitted.

In the above-described embodiment, the SiC wafer 40 is etched uniformly in the thinning step. However, in the first modification, the amount of etching is varied depending on the position (particularly, the position in the direction along the surface to be treated) of the SiC wafer 40. To be specific, in the thinning step of the first modification, the amount of etching on the outer edge part of the SiC wafer 40 is less than the amount of etching in other regions (for example, a region of the epitaxial forming, the central region). This results in the manufacturing of the SiC wafer 40 having a larger thickness of the outer edge part than that in other regions, as shown in FIG. 9. The yield is not decreased since the semiconductor device is not formed on the outer edge part. The mechanical strength of the SiC wafer 40 can be improved by increasing the thickness of the outer edge part. This can improve the yield.

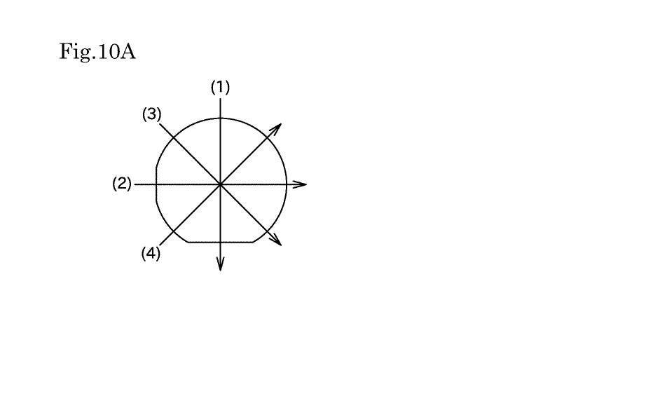

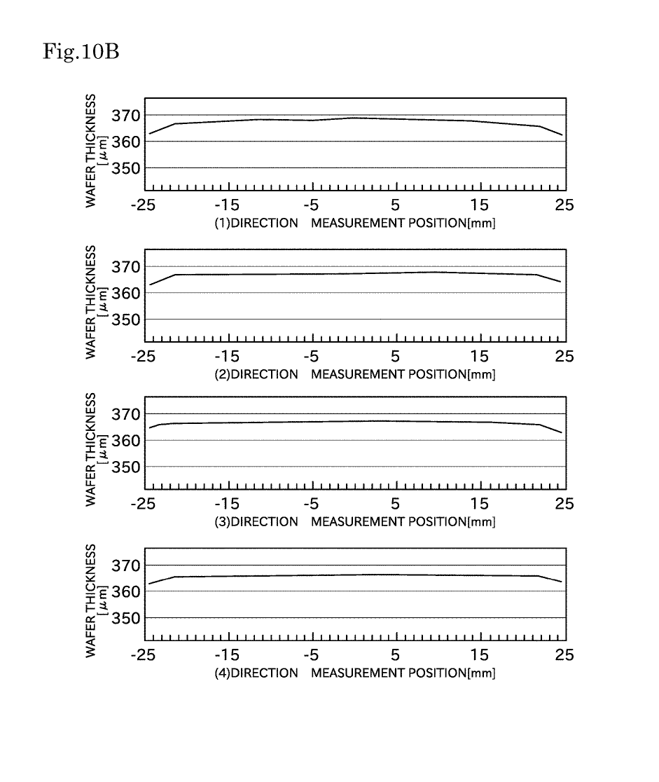

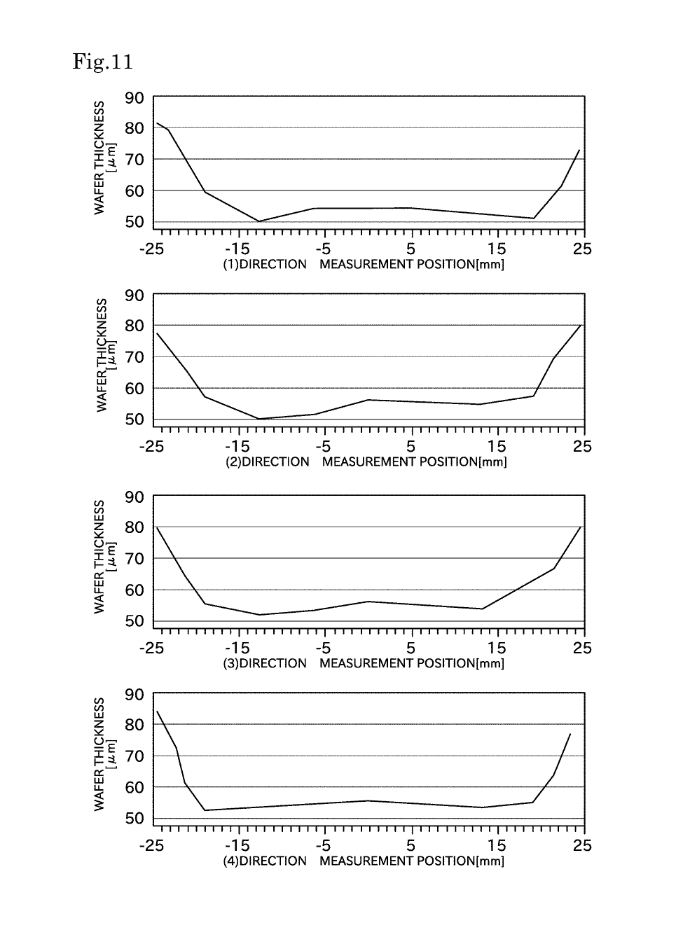

FIG. 10A, FIG. 10B and FIG. 11 are graphs showing the experiment result which demonstrates that the processing of the first modification is executable. FIG. 10A, FIG. 10B and FIG. 11 show the experiment result in which the Si vapor pressure etching (thinning step) is performed with the less amount of etching on the outer edge part than that in the other regions. FIG. 10A is a drawing describing the direction in which the thickness of the SiC wafer 40 is measured. FIG. 10B is a graph showing the thickness of the SiC wafer 40 with respect to every direction shown in FIG. 10A prior to the Si vapor pressure etching. As shown in FIG. 10B, although the SiC wafer 40 prior to the Si vapor pressure etching had a slight smaller thickness of the outer edge part than that in the other regions, the surface was basically planar.

FIG. 11 is a graph showing the thickness of the SiC wafer 40 after the Si vapor pressure etching (after the thinning step) in each direction of FIG. 10A. The different environment between the outer edge part of the SiC wafer 40 and the other region allows, as shown in FIG. 11, the amount of etching on the outer edge part to be smaller than that in the other region. Therefore, a thin SiC wafer 40 having the excellent mechanical strength can be manufactured In the first modification, although the thinning step of the SiC wafer 40 and the thickness forming step of the outer edge part are performed simultaneously, they may be performed individually.

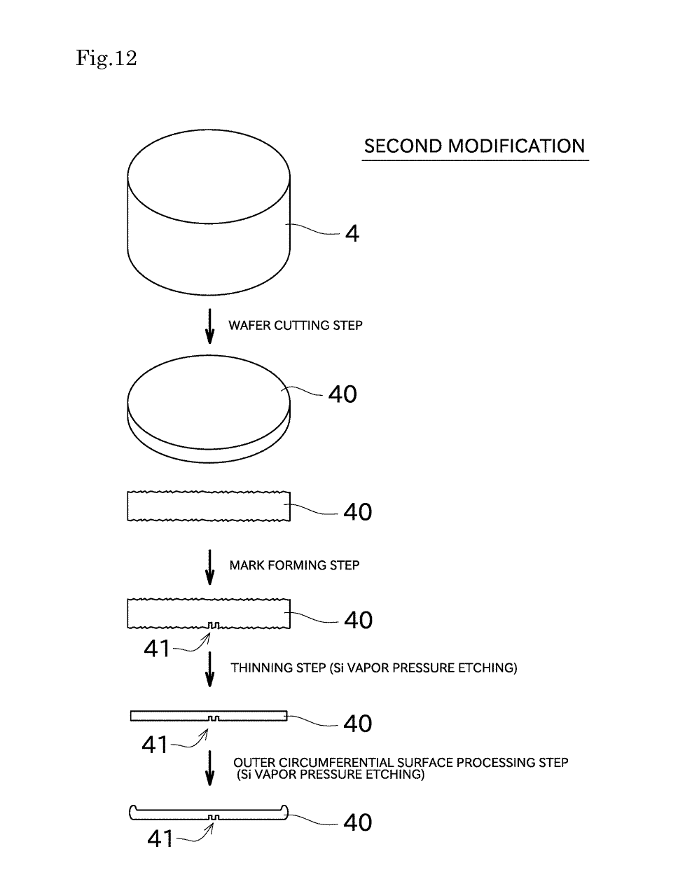

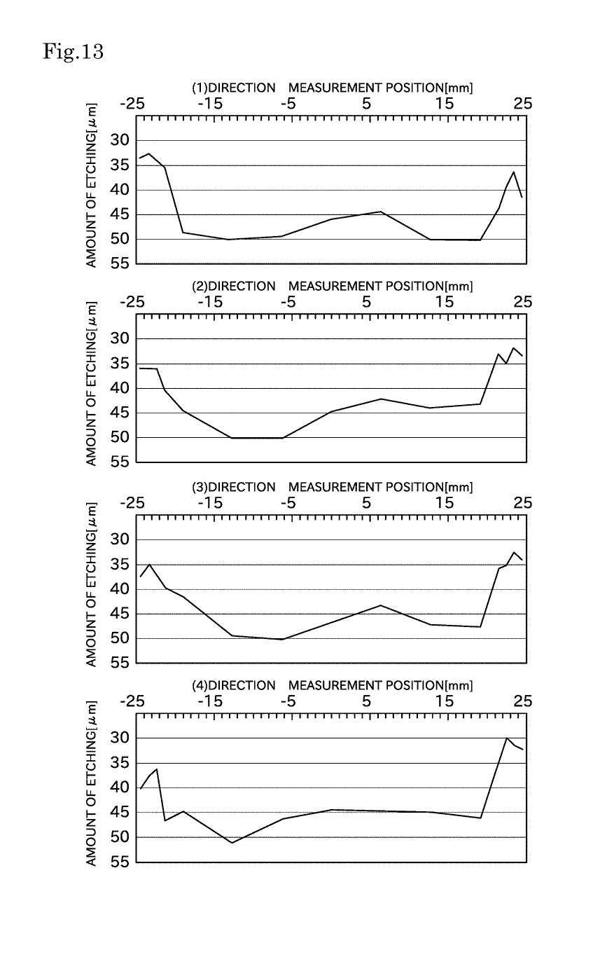

Next, the second modification of the above-described embodiment will be described with reference to FIG. 12 and FIG. 13. In a description of this modification, configuration parts identical or similar to those of the above-described embodiment will be denoted by the same reference numerals as those of the above-described embodiment, and descriptions thereof may be omitted.

In the above-described embodiment, the outer circumferential surface processing step is performed by machining or the like. In the second modification, as shown in FIG. 12, the outer circumferential surface processing step is performed by the Si vapor pressure etching. In the second modification, although the outer circumferential surface processing step is performed after the thinning step, it may be performed between the wafer cutting step and the mark forming step, similarly to the above-described embodiment.

Similarly to the first modification, for example, the heating temperature has the distribution without making uniform the surrounding environment of the SiC wafer 40, which can have the distribution in the amount of etching. In the second modification, the amount of etching in the further outside (that is, in the outer circumferential surface) is larger than that on the outer edge part while reducing the amount of etching on the outer edge part. Accordingly, as shown in FIG. 12, chamfering of the SiC wafer 40 can be performed using the Si vapor pressure etching while increasing the thickness of the outer edge part for the purpose of reinforcement.

FIG. 13 is a graph showing the experiment result which demonstrates that the processing of the second modification is executable. FIG. 13 is a graph showing the distribution of the amount of etching after the Si vapor pressure etching in each direction of FIG. 10A. The graph of FIG. 13 shows that the amount of etching on the outer edge part is smaller than that in the central region (the thickness of the outer edge part is larger), similarly to the graph of FIG. 11. Additionally, in the graph of FIG. 13, the smallest amount of etching can be found near the edge of the measurement position, and the slight larger amount of etching can be found in the further edge side. Accordingly, it can be seen that the edge (the outer circumferential surface) in the measurement position of the SiC wafer 40 was etched and the outer circumferential surface was chamfered.

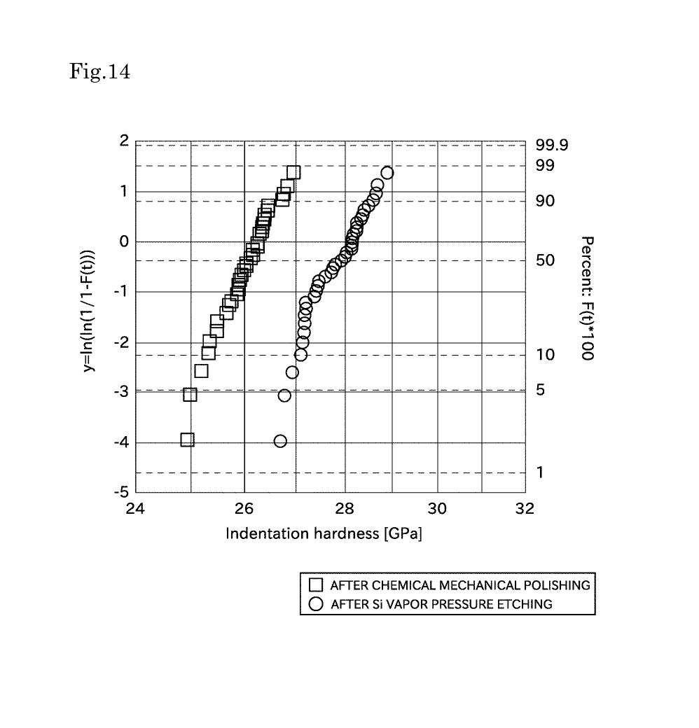

Next, the difference between the hardness of the SiC wafer after the Si vapor pressure etching and the hardness of the SiC wafer after the chemical mechanical polishing will be described with reference to FIG. 14. FIG. 14 is a diagram showing Weibull distribution as a result of the hardness measurement of the SiC wafer after the chemical mechanical polishing and the SiC wafer after the Si vapor pressure etching using nano indentation method.

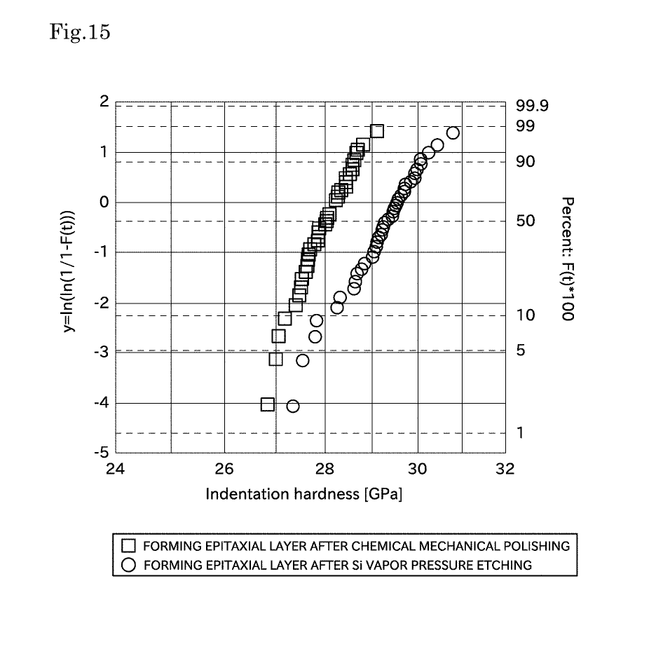

In this experiment, the surface of the SiC wafer of 4H—SiC having an off angle of 4 degree in [11-20] direction was measured as the target of the hardness measurement. The surface (main surface) of the SiC wafer meant the face for forming the semiconductor element. In this experiment, it meant the Si-face, that is, (0001) face. For the one SiC wafer, its surface was subjected to the chemical mechanical polishing after the mechanical polishing. For the other SiC wafer, its surface was removed to 40 μm by the Si vapor pressure etching at 1850 □ after the mechanical polishing. Although the present invention is configured to perform the thinning step by the Si vapor pressure etching, the Si vapor pressure etching is performed after the mechanical polishing since this experiment (the after-mentioned experiment of FIG. 15 as well) is intended for the hardness measurement of the SiC wafer surface.

The known nano indentation method was used as a method for measuring the hardness. To be specific, the load of 500 mN was applied to two SiC wafers to be measured, which could set the indentation of about 1 μm. That is, in this measurement, the hardness on the surface of the SiC wafer was measured. The hardness [GPa] was calculated by calculating the load/contact projected area. FIG. 14 shows Weibull distribution as a result of the multiple measurements.

FIG. 14 shows that the SiC wafer after the Si vapor pressure etching has the hardness harder than that of the SiC wafer after the chemical mechanical polishing. In the result of this experiment, the hardness was 27 GPa or more (in other words, at least partly the hardness was 27 GPa or more) as long as the Si vapor pressure etching was performed. Naturally, the hardness of 27.5 GPa, 28 GPa or more cannot be achieved except for the SiC wafer in which the Si vapor pressure etching is performed. In a description from other view, when compared to the hardness at 50% in the probability distribution, the hardness of the SiC wafer after the chemical mechanical polishing is about 26 GPa. On the other hand, the hardness of the SiC wafer after the Si vapor pressure etching is about 28G Pa. As such, the Si vapor pressure etching enables the hardness at 50% in the probability distribution to be larger than 26 GPa (to be specific, 26 GPa, 27 GPa, 27.5 GPa or more).

Accordingly, the SiC wafer having a high hardness can be manufactured by using the Si vapor pressure etching, as compared with a case of using the chemical mechanical polishing. This enables the SiC wafer to have a sufficient strength even if the thickness is decreased to 100 μm or less, as this embodiment. It is considered that the hardness is increased since the SiC wafer in which the Si vapor pressure etching is performed, has less crystal defects than that in the SiC wafer in which the chemical mechanical polishing is performed. The experiment by the applicants demonstrated that the SiC wafer in which the Si vapor pressure etching is performed had a higher hardness than that of the SiC wafer in which the hydrogen etching is performed. Additionally, the experiment by the applicants demonstrated that the SiC wafer after the Si vapor pressure etching had a higher bending strength than that of the SiC wafer after the mechanical polishing.

Next, in a state that the epitaxial layer is formed on the above-described two kinds of SiC wafers, the measurement result of the hardness using nano indentation method as well will be described with reference to FIG. 15. FIG. 15 is a diagram showing Weibull distribution as a result of the hardness measurement of the SiC wafer in which the epitaxial layer is formed after the chemical mechanical polishing and the SiC wafer in which the epitaxial layer is formed after the Si vapor pressure etching after mechanical polishing using nano indentation method.

In the method of this embodiment, since the hardness of about 1 μm on the surface is measured, it can be recognized that the measurement result of FIG. 15 represents the hardness of the epitaxial layer. FIG. 15 shows that the epitaxial layer that is formed after the Si vapor pressure etching is harder than the epitaxial layer that is formed after the chemical mechanical polishing. In this experiment result, the hardness of 29.5 GPa or more cannot be achieved except for the epitaxial layer formed after the Si vapor pressure etching (in other words, at least partly the hardness was 29.5 GPa). Naturally, the hardness of 30 GPa, 30.5 Pa or more cannot be achieved except for the epitaxial layer formed after the Si vapor pressure etching. In a description from other view, when compared to the hardness at 50% in the probability distribution, the hardness of the epitaxial layer formed after the chemical mechanical polishing is about 28 GPa. On the other hand, the hardness of the epitaxial layer formed after the Si vapor pressure etching is about 29.5 GPa. As such, the Si vapor pressure etching enables the hardness at 50% in the probability distribution to be larger than 28 GPa (to be specific, 28.5 GPa, 29 GPa, 29.5 GPa or more).

As such, it is considered that the hardness of the epitaxial layer has variations because of less number of crystal defects is propagated to the epitaxial layer since the SiC wafer in which the Si vapor pressure etching is performed has less crystal defects than that in the SiC wafer in which the chemical mechanical polishing is performed.

As described above, the method for manufacturing the thin SiC wafer 40 of this embodiment includes the thinning step. In the thinning step, the thickness of the SiC wafer 40 can be decreased to 100 μm or less by performing the Si vapor pressure etching to the SiC wafer 40 after it is cut of the ingot 4.

Accordingly, in the Si vapor pressure etching, since the processing damage and the stress is not applied to the SiC wafer 40 during the etching, hairline crack or the like is not occurred even if the SiC wafer is thinned to 100 μm or less. Since the Si vapor pressure etching enables the surface to be planarized at a molecular level, a polishing step is unnecessary. Furthermore, since the Si vapor pressure etching can be performed at a high speed, the thinning step can be performed in a short time even in a case of considerably thinning the SiC wafer 40.

Although a preferred embodiment and modifications of the present invention have been described above, the above-described configuration can be modified, for example, as follows.

The manufacturing steps described in FIG. 3 and the like are merely illustrative ones, the order of steps may be changed, a part of steps may be omitted, or other steps may be added. In the above-described embodiment and modifications, although the thinning step is performed only by the Si vapor pressure etching, instead of this, it may be performed by the mechanical grinding and the Si vapor pressure etching. In this case, the mechanical grinding is firstly performed and then the Si vapor pressure etching is performed, which can remove the processing damage occurred during the cutting and the mechanical grinding. This can manufacture the SiC wafer having the same strength as that of the SiC wafer 40 of the above-described embodiment. In order to remove the processing damage, it is preferable that the thickness of at least 20 μm (more preferably, at least 50 μm) from the surface of the SiC wafer is etched by using the Si vapor pressure etching.

The temperature condition, the pressure condition, and the like, adopted in the above-described embodiment are illustrative examples, and they can be changed as appropriate. Moreover, a heating apparatus other than the above-described high-temperature vacuum furnace 10, the SiC wafer 40 made of polycrystalline SiC, and a container having a shape or materials different from that of the crucible 30 are adoptable. For example, a storing container may have a cylindrical shape, a cubic shape, or a rectangular parallelepiped shape.

What is claimed is:

1. A method for manufacturing a thin SiC wafer by processing a SiC wafer after cutting out of an ingot comprising:
a thinning step for thinning a thickness of the SiC wafer after cutting out of the ingot; wherein
in the thinning step, performing a Si vapor pressure etching in which a surface of the SiC wafer is etched by heating the SiC wafer enables to decrease the thickness of the SiC wafer to 100 μm or less.

2. The method for manufacturing the thin SiC wafer according to claim 1, wherein
in the thinning step, the Si vapor pressure etching is performed to the SiC wafer after cutting out of the ingot, the SiC wafer that has not been subjected to mechanically grinding for adjusting the thickness of the SiC wafer.

3. The method for manufacturing the thin SiC wafer according to claim 1, wherein
in the thinning step, the thickness of the SiC wafer is decreased while removing the surface roughness of the SiC wafer formed at a time of cutting out of the ingot.

4. The method for manufacturing the thin SiC wafer according to claim 1, wherein
in the thinning step, the thickness of the SiC wafer is removed by 100 μm or more.

5. The method for manufacturing the thin SiC wafer according to claim 1, wherein
in the thinning step, at least the Si vapor pressure etching in which an etching rate of a surface to be treated is 500 nm/min or more is performed.

6. The method for manufacturing the thin SiC wafer according to claim 1, wherein
when one surface for forming an epitaxial layer in the SiC wafer is specified as a main surface, in the thinning step, both of the main surface of the SiC wafer and a back surface of the main surface are etched.

7. The method for manufacturing the thin SiC wafer according to claim 1, wherein
in the thinning step, the Si vapor pressure etching is performed to the SiC wafer in which a mark is formed, the mark that shows information by removing the surface to be formed into a predetermined shape.

8. The method for manufacturing the thin SiC wafer according to claim 7, wherein
prior to the thinning step, a mark forming step for forming the mark on the SiC wafer is performed.

9. The method for manufacturing the thin SiC wafer according to claim 1, wherein
in the thinning step, the Si vapor pressure etching is performed such that an amount of etching is varied depending on a position of the SiC wafer.

10. The method for manufacturing the thin SiC wafer according to claim 9, wherein
in the thinning step, the Si vapor pressure etching is performed such that the thickness in an outer edge part of the SiC wafer is larger than the thickness in the central region and the thickness in the central region is 100 μm or less.

11. The method for manufacturing the thin SiC wafer according to claim 9, wherein
in the thinning step, the SiC wafer is chamfered while decreasing the thickness of the SiC wafer.

12. A method for manufacturing a thin SiC wafer by processing a SiC wafer after cutting out of an ingot comprising:
a thinning step for thinning a thickness of the SiC wafer after cutting out of the ingot; wherein
in the thinning step, after the thickness of the SiC wafer is decreased by mechanically grinding, the thickness is further decreased by performing a Si vapor pressure etching in which a surface of the SiC wafer is etched by heating the SiC wafer under Si vapor pressure, which decreases the thickness of the SiC wafer to 100 μm or less.

13. A SiC wafer, in its surface, having a mark showing information depending on a removed shape that is formed into a predetermined shape by removing, and having the thin thickness of 100 μm or less.

14. The SiC wafer according to claim 13, the wafer before forming an epitaxial layer, including a region having a hardness of 27 GPa or more when the surface is measured by using nano indentation method under a condition that the load is 500 mN or the indentation is 1 μm.

15. The SiC wafer according to claim 13, on its surface, having an epitaxial layer, including a region having the hardness of 29.5 GPa or more when the surface of the epitaxial layer is measured by using nano indentation method under a condition that the load is 500 mN or the indentation is 1 μm.

16. The SiC wafer according to claim 13, the wafer before forming an epitaxial layer, having a higher hardness, when the surface is measured by using nano indentation method under a condition that the load is 500 mN or the indentation is 1 μm, than the hardness of the SiC wafer after performing a chemical mechanical polishing.

17. The SiC wafer according to claim 13, wherein
a central region and an outer edge part are provided,
the thickness of the outer edge part is larger than the thickness of the central region.
